(19) United States
(12) Patent Application Publication
(10) Pub. No.: US 2025/0267802 A1
(43) Pub. Date: Aug. 21, 2025

(54) ELECTRONIC COMPONENT

(71) Applicant: COMPAL ELECTRONICS, INC., Taipei City (TW)

(72) Inventor: Chia-Ming Chi, Taipei City (TW)

(73) Assignee: COMPAL ELECTRONICS, INC., Taipei City (TW)

(21) Appl. No.: 19/047,574

(22) Filed: Feb. 6, 2025

(30) Foreign Application Priority Data
Feb. 16, 2024 (TW) 113105440

(51) Int. Cl. H05K 5/00; H05K 5/02; H05K 5/04

(52) U.S. Cl. CPC H05K 5/0069; H05K 5/0217; H05K 5/0247; H05K 5/04

(57) ABSTRACT

An electronic component includes a circuit board and a metal casing. The circuit board includes at least one opening and at least one pad. The circuit board is detachably connected to the metal casing. The metal casing includes a plate, a first connecting member and a second connecting member. The plate is connected to the first connecting member and the second connecting member. The first connecting member and the second connecting member partially pass through the at least one opening and are connected to the circuit board. The first connecting member and the second connecting member contact the at least one pad, so that the circuit board is electrically connected to the plate.

### CROSS-REFERENCE TO RELATED APPLICATION

This application claims the priority benefit of Taiwan application serial no. 113105440, filed on Feb. 16, 2024. The entirety of the above-mentioned patent application is hereby incorporated by reference herein and made a part of this specification.

### TECHNICAL FIELD

This disclosure relates to a component, and in particular to an electronic component.

### DESCRIPTION OF RELATED ART

The circuit board and casing of present-day devices are fastened together through screws. During disassembly or assembly, screws and additional tools (such as screwdrivers) are required to fasten with manual labor, thus becoming inconvenient to use.

### SUMMARY

This disclosure provides an electronic component that is easy to disassemble and assemble.

The electronic component of this disclosure includes a circuit board and a metal casing. The circuit board includes at least one opening and at least one pad. The circuit board is detachably connected to the metal casing. The metal casing includes a plate, a first connecting member, and a second connecting member. The plate is connected to the first connecting member and the second connecting member. The first connecting member and the second connecting member partially pass through at least one opening and are connected to the circuit board. The first connecting member and the second connecting member are in contact with at least one pad so that the circuit board is electrically connected to the plate.

Based on the above, the metal casing of the electronic component is detachably connected to the circuit board through the first connecting member and the second connecting member. The first connecting member and the second connecting member are in contact with the pad of the circuit board so that the circuit board is electrically connected to the plate. The circuit board is easy to assemble onto the metal casing or disassemble off the metal casing.

### BRIEF DESCRIPTION OF THE DRAWINGS

FIG. 1 and FIG. 2 illustrate the assembly process of an electronic component according to an embodiment of this disclosure.

FIG. 3 is a schematic cross-sectional view of the electronic component of FIG. 1 after assembly.

FIG. 4 is a top view of the metal casing of FIG. 1.

FIG. 5 is a top view of the electronic component of FIG. 3.

FIG. 6A is a schematic cross-sectional view of an electronic component according to another embodiment of this disclosure.

FIG. 6B is a top view of the electronic component of FIG. 6A.

FIG. 7 is a schematic cross-sectional view of an electronic component according to another embodiment of this disclosure.

FIG. 8 is a top view of the metal casing of FIG. 7.

FIG. 9 is a top view of the electronic component of FIG. 7.

FIG. 10 is a schematic cross-sectional view of an electronic component according to another embodiment of this disclosure.

FIG. 11 is a top view of the electronic component of FIG. 10.

FIG. 12 is a schematic diagram of the disassembly process of the electronic component of FIG. 10.

FIG. 13 is a schematic cross-sectional view of an electronic component of another embodiment of this disclosure.

FIG. 14 is a top view of an electronic component according to another embodiment of this disclosure.

FIG. 15 is a schematic cross-sectional view of an electronic component of another embodiment of this disclosure.

FIG. 16 is a top view of the electronic component of FIG. 15.

### DETAILED DESCRIPTION OF DISCLOSED EMBODIMENTS

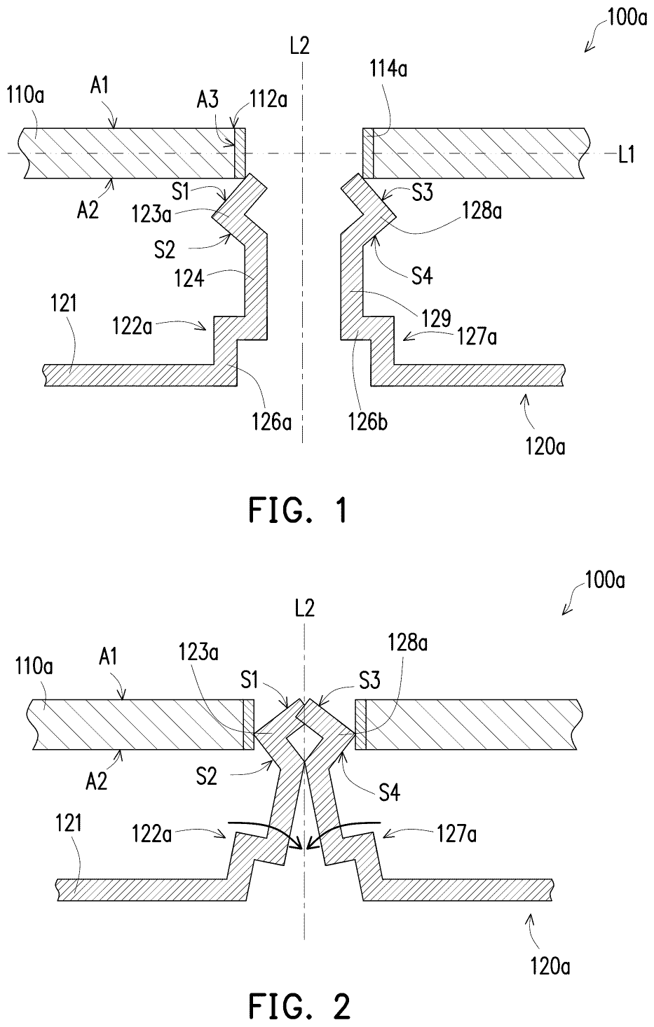

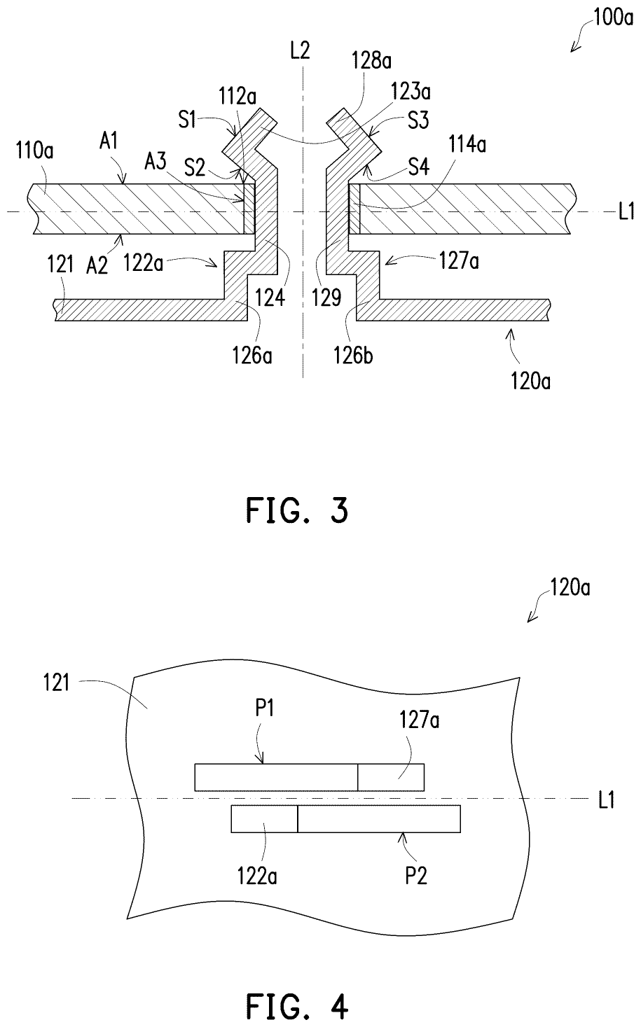

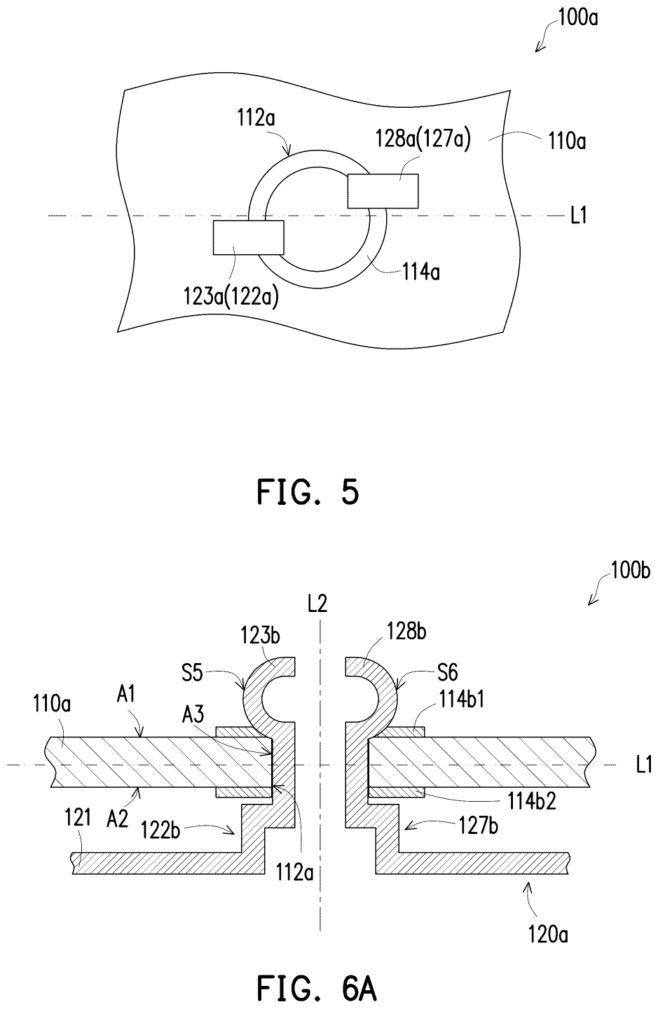

FIG. 1 and FIG. 2 illustrate the assembly process of an electronic component according to an embodiment of this disclosure. FIG. 3 is a schematic cross-sectional view of the electronic component of FIG. 1 after assembly. FIG. 4 is a top view of the metal casing of FIG. 1. FIG. 5 is a top view of the electronic component of FIG. 3. Please refer to FIG. 1 to FIG. 5 simultaneously. The electronic component 100a includes a circuit board 110a and a metal casing 120a. The circuit board 110a is detachably connected to the metal casing 120a. The circuit board 110a includes at least one opening 112a and at least one pad 114a. The metal casing 120a includes a plate 121, a first connecting member 122a, and a second connecting member 127a. The plate 121 is connected to the first connecting member 122a and the second connecting member 127a.

As shown in FIG. 3, the first connecting member 122a and the second connecting member 127a partially pass through the opening 112a and are detachably connected to the circuit board 110a. The first connecting member 122a and the second connecting member 127a have a certain flexibility and may move (e.g., bend) relatively to the plate 121 to lock or unlock from the circuit board 110a. The first connecting member 122a and the second connecting member 127a contact the pad 114a of the circuit board 110a so that the circuit board 110a is electrically connected to the plate 121.

As shown in FIG. 3 and FIG. 4, the first connecting member 122a and the second connecting member 127a of this embodiment are formed through stamping, for example. Two corresponding holes P1 and P2 are formed on the plate 121. The plate 121, the first connecting member 122a, and the second connecting member 127a are integrated as a whole but are not limited thereto. The first connecting member 122a and the second connecting member 127a may replace screws so that the circuit board 110a and the metal casing 120a may be disassembled and assembled without tools and screws, thereby simplifying the components of the electronic component 100a, reaching the effect of improving manufacturing efficiency, reducing manufacturing time, improving recycling efficiency, miniaturizing the fixed structure (the first connecting member 122a and the second connecting member 127a), and reducing the wiring layout restrictions and the component setup restrictions of the circuit board 110a.

As shown in FIG. 1, the first connecting member 122a includes a first convex part 123a and a first connecting part 124 connected to each other, and the first connecting part 124 is connected to the plate 121. The first convex part 123a includes a first inclined surface S1, and the first inclined surface S1 faces away from the circuit board 110a. The first convex part 123a (first connecting member 122a) optionally includes a second inclined surface S2. The second inclined surface S2 faces the circuit board 110a, and is connected to the first inclined surface S1. The first inclined surface S1 and the second inclined surface S2 are inclined to a first axis L1 and a second axis L2, so the cross-sectional shape of the first convex part 123a is V-shaped. The first connecting part 124 extends along the second axis L2. The first axis L1 is parallel to the plate 121, and the second axis L2 is perpendicular to the first axis L1 and the circuit board 110a.

The second connecting member 127a includes a connected second convex part 128a and a second connecting part 129, and the second connecting part 129 is connected to the plate 121. The second convex part 128a includes a third inclined surface S3, and the third inclined surface S3 faces away from the circuit board 110a. The second convex part 128a (second connecting member 127a) optionally includes a fourth inclined surface S4. The fourth inclined surface S4 faces the circuit board 110a, and is connected to the third inclined surface S3. The third inclined surface S3 and the fourth inclined surface S4 are inclined to the first axis L1 and the second axis L2, so the cross-sectional shape of the second convex part 128a is V-shaped. The second connecting part 129 extends along the second axis L2. The first connecting member 122a and the second connecting member 127a of this embodiment have the same structure but are not limited thereto.

As shown in FIG. 4, the first connecting member 122a and the second connecting member 127a are staggered on the first axis L1 but are not limited thereto. As shown in FIG. 5, the number of the opening 112a of the circuit board 110a of this embodiment is one, the number of pad 114a is one, and the pad 114a is connected to an inner wall A3 of the corresponding opening 112a, but it is not limited thereto.

FIG. 1 to FIG. 3 illustrate the disassembly and assembly process of the circuit board and metal casing. As shown in FIG. 1, during the process of assembling the circuit board 110a and the metal casing 120a, the circuit board 110a may move along the second axis L2 close to the metal casing 120a. The opening 112a of the circuit board 110a corresponds to the first connecting member 122a and the second connecting member 127a. A bottom surface A2 (pad 114a) of circuit board 110a contacts the first inclined surface S1 (first convex part 123a) and the third inclined surface S3 (second convex part 128a). The bottom surface A2 faces the plate 121.

As shown in FIG. 2, the circuit board 110a continues to move closer to the plate 121, and the first inclined surface S1 (the first convex part 123a) and the third inclined surface S3 (the second convex part 128a) are pushed by the bottom surface A2 of the circuit board 110a, and the first connecting member 122a is moved closer to the second connecting member 127a, and the second connecting member 127a is moved closer to the first connecting member 122a. The first connecting member 122a and the second connecting member 127a enter the opening 112a, and the circuit board 110a may continue to move toward the plate 121. As shown in FIG. 3, the circuit board 110a moves into position. The first convex part 123a and the second convex part 128a pass through the opening 112a and are exposed on the circuit board 110a from the opening 112a. The first connecting part 124 and the second connecting part 129 are at least partially located inside the opening 112a. The first connecting member 122a and the second connecting member 127a rely on their own flexibility to return to their positions in FIG. 3 from the positions in FIG. 2. At this point, the circuit board 110a and metal casing 120a are assembled.

As shown in FIG. 5, the projection part of at least one of the assembled first connecting member 122a and the second connecting member 127a on the circuit board 110a is located in the opening 112a so that at least one of the first connecting member 122a and the second connecting member 127a is engaged with the circuit board 110a. In this embodiment, the projection part of the first connecting member 122a and the second connecting member 127a to the circuit board 110a is located at the opening 112a, and the first connecting member 122a and the second connecting member 127a are engaged with the circuit board 110a. The first connecting part 124 of the first connecting member 122a and the second connecting part 129 of the second connecting member 127a are in contact with the pad 114a so that the circuit board 110a is coupled to the plate 121 and grounded to maintain the grounding of the circuit board 110a and noise shielding function of the metal casing 120a.

Since the pad 114a is set up on the inner wall A3 of the opening 112a, a top surface A1 and a bottom surface A2 of the circuit board 110a may be used entirely for laying circuits and electronic components (not shown), thereby increasing the wiring and component installation space on the top surface A1 and the bottom surface A2 of the circuit board 110a. The top surface A1 faces away from the plate 121 and is opposite to the bottom surface A2.

As shown in FIG. 3, the first connecting member 122a further includes a positioning part 126a, and the second connecting member 127a further includes a positioning part 126b. The positioning part 126a is connected between the first connecting part 124 and the plate 121 in a bending manner, and the positioning part 126b is connected between the second connecting part 129 and the plate 121 in a bending manner. The positioning parts 126a and 126b are adapted to block the circuit board 110a from moving along the second axis L2 to ensure that a certain distance is maintained between the circuit board 110a and the plate 121.

When the circuit board 110a is to be disassembled from the metal casing 120a, the circuit board 110a may be forced to move from the position of FIG. 3 to the position of FIG. 2. During the movement of circuit board 110a, the circuit board 110a moves away from the plate 121 along the second axis L2. The top surface A1 (pad 114a) of the circuit board 110a pushes against the second inclined surface S2 (first convex part 123a) and the fourth inclined surface S4 (second convex part 128a) so that the first connecting member 122a and the second connecting member 127a move to the position of FIG. 2, the first convex part 123a of the first connecting member 122a and the second convex part 128a of the second connecting member 127a enter the opening 112a, and the first connecting member 122a and the second connecting member 127a disengage from the circuit board 110a.

Then, the circuit board 110a may further move away from the metal casing 120a from the position of FIG. 2 to the position of FIG. 1. After the circuit board 110a is separated from the metal casing 120a (see FIG. 1), the first connecting member 122a and the second connecting member 127a return to their positions in FIG. 1 by their own flexibility. At this point, the disassembly of the circuit board 110a and the metal casing 120a is completed. The circuit board 110a and the metal casing 120a may be disassembled and assembled without tools.

In addition, as shown in FIG. 5, the shape of the opening 112a is, for example, a circle, and the opening 112a may be an opening used for setting screws in a conventional circuit board. Thereby, the metal casing 120a is applicable to the conventional circuit board, thus improving the convenience of use of the electronic component 100a (metal casing 120a). The number, structure, and setup arrangements of the opening 112a, the pad 114a, the first connecting member 122a, and the second connecting member 127a are not limited to this embodiment.

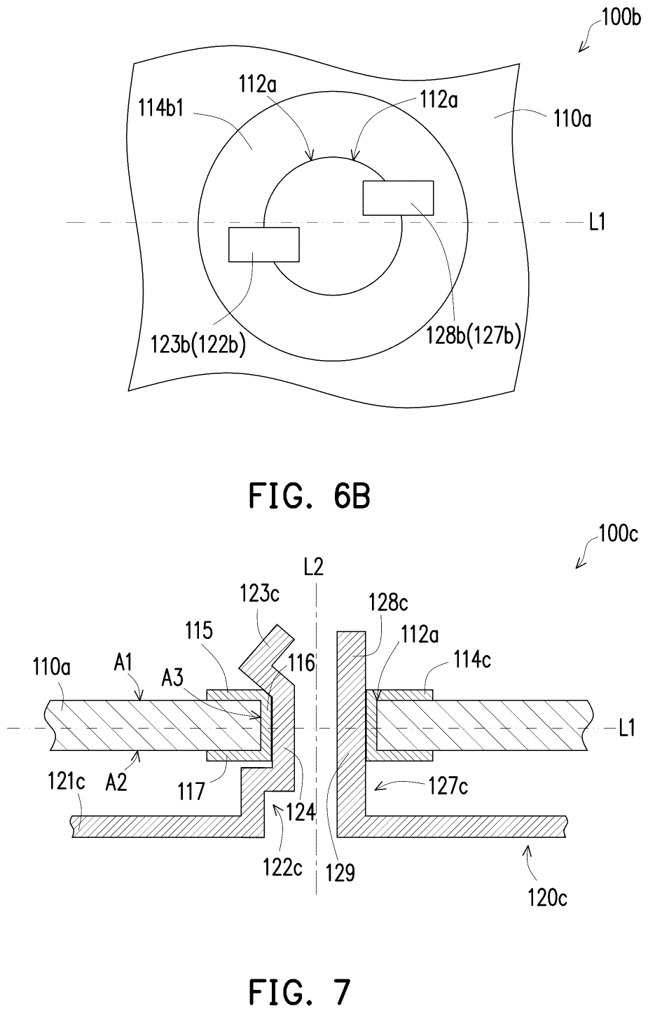

FIG. 6A is a schematic cross-sectional view of an electronic component according to another embodiment of this disclosure. FIG. 6B is a top view of the electronic component of FIG. 6A. Please refer to FIG. 3, FIG. 6A and FIG. 6B simultaneously. The electronic component 100b of this embodiment is similar to the embodiment mentioned above. The difference between the two is that the first convex part 123b of the first connecting member 122b of this embodiment includes a curved surface S5, and the second convex part 128b of the second connecting member 127b includes another arc surface S6. The first convex part 123b and the second convex part 128b have a C-shaped cross-sectional shape. The number of the pads 114b1 and 114b2 is two, and the two pads 114b1 and 114b2 surround the opening 112a.

The pad 114b1 is located on the top surface A1 of the circuit board 110a, and the pad 114b2 is located on the bottom surface A2 of the circuit board 110a. The first convex part 123b and the second convex part 128b are in contact with the pad 114b1, so the circuit board 110a is coupled to the plate 121 and grounded. The metal casing 120b may be disassembled and assembled without tools through the two curved surfaces S5 and S6 and the circuit board 110a. The electronic component 100b of this embodiment has the same effect as the embodiment mentioned above and will not be described again.

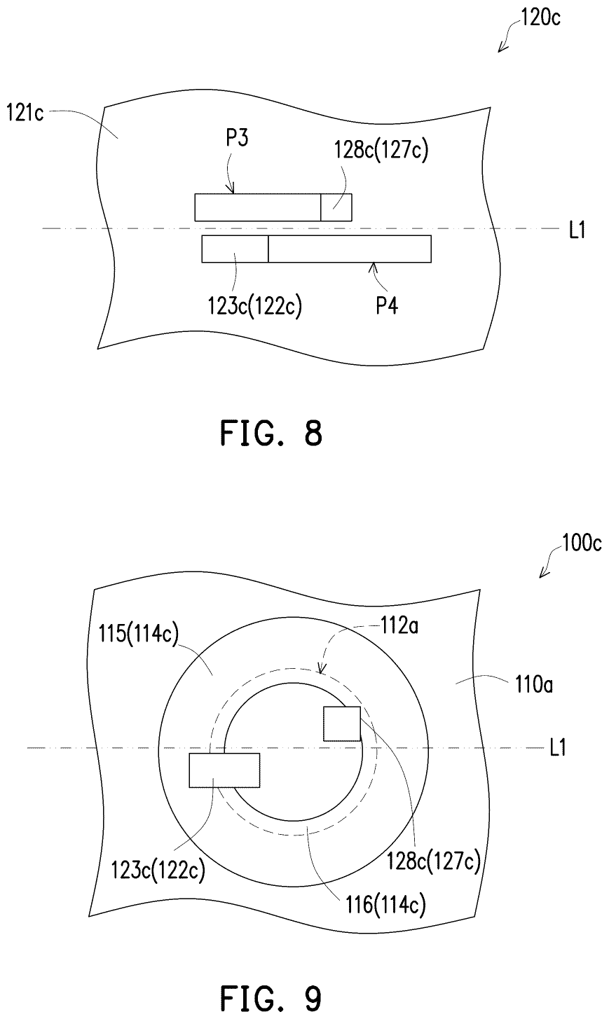

FIG. 7 is a schematic cross-sectional view of an electronic component according to another embodiment of this disclosure. FIG. 8 is a top view of the metal casing of FIG. 7. FIG. 9 is a top view of the electronic component of FIG. 7. Please refer to FIG. 3, FIG. 7 to FIG. 9 simultaneously. The electronic component 100c of this embodiment is similar to the embodiment mentioned above. The difference between the two is that the structure of the first connecting member 122c of this embodiment differs from the structure of the second connecting member 127c. The cross-sectional shape of the first convex part 123c of the first connecting member 122c is V-shaped. The second convex part 128c of the second connecting member 127c and the second connecting part 129 extend along the second axis L2, and the cross-sectional shape of the second convex part 128c is a rectangle. The size of the hole P4, which corresponds to the first connecting member 122c in the plate 121c of the metal casing 120c, is larger than the size of the hole P3, which corresponds to the second connecting member 127c.

As shown in FIG. 7, the pad 114c includes a first part 115 and a second part 116 that are connected. The first part 115 is located on the top surface A1 of the circuit board 110a, and the second part 116 is connected to the inner wall surface A3 of the opening 112a. The pad 114c optionally includes a third part 117. The third part 117 is located on the bottom surface A2 of the circuit board 110a and is connected to the second part 116. The first convex part 123c of the first connecting member 122c contacts the first part 115 of the pad 114c, the first connecting part 124 of the first connecting member 122c, and the second connecting part 129 of the second connecting member 127c contacts the second part 116 of the pad 114c. As shown in FIG. 9, the projection part of the first connecting member 122c to the circuit board 110a is located at the opening 112a. The electronic component 100c of this embodiment has the same effect as the embodiment mentioned above and will not be described again.

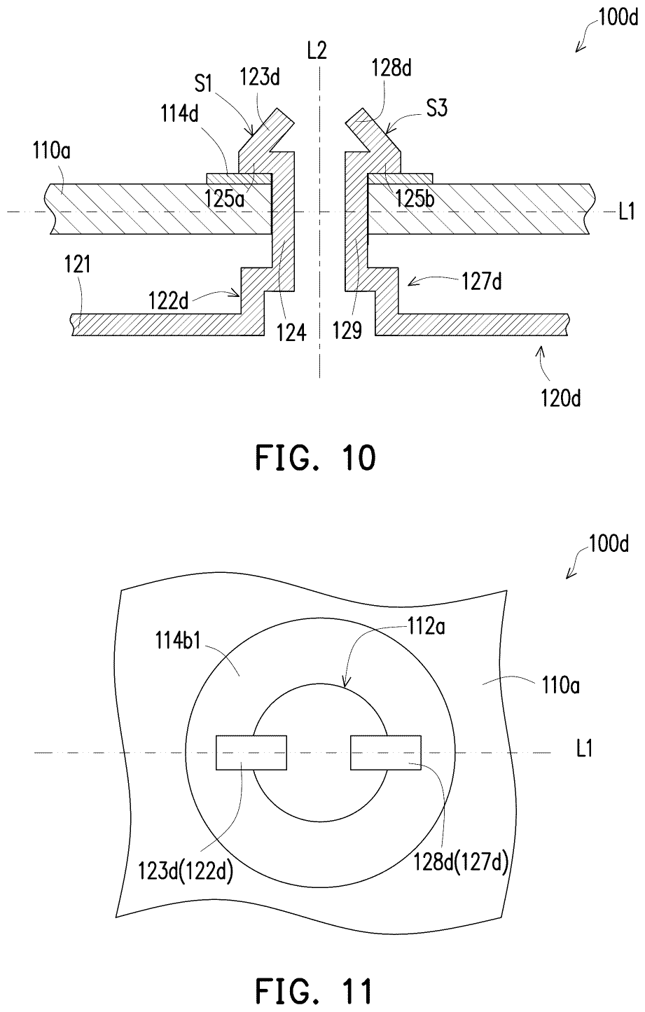

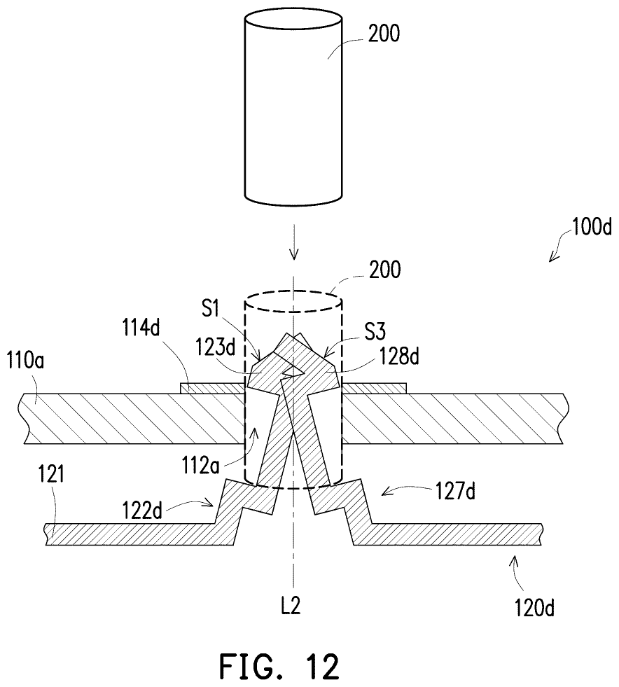

FIG. 10 is a schematic cross-sectional view of an electronic component according to another embodiment of this disclosure. FIG. 11 is a top view of the electronic component of FIG. 10. FIG. 12 is a schematic diagram of the disassembly process of the electronic component of FIG. 10. Please refer to FIG. 3, FIG. 10 to FIG. 12 simultaneously. The electronic component 100d of this embodiment is similar to the embodiment mentioned above. The difference between the two is that the first convex part 123d of the first connecting member 122d of this embodiment includes a horizontal part 125a, and the second convex part 128d of the second connecting member 127d includes another horizontal part 125b. The horizontal parts 125a and 125b are parallel to the first axis L1.

As shown in FIG. 10 and FIG. 11, the horizontal part 125a is connected to the first inclined surface S1 and the first connecting part 124, and is located between the first inclined surface S1 and the first connecting part 124. The horizontal part 125b is connected to the third inclined surface S3 and the second connecting part 129, and is located between the third inclined surface S3 and the second connecting part 129. The first connecting member 122d and the second connecting member 127d are aligned to each other on the first axis L1. The number of pad 114d in this embodiment is one, and pad 114d is located on the top surface A1 of the circuit board 110a. The two horizontal parts 125a and 125b are in contact with the pad 114d, so that the circuit board 110a is coupled to the plate 121.

As shown in FIG. 12, the user may disassemble and assemble the circuit board 110a and the metal casing 120d through a tool 200. The tool 200 has a cylindrical shape matching the shape of the opening 112a. FIG. 12 schematically illustrates the tool 200 located in the opening 112a with a dashed line. During the assembly process of the circuit board 110a and the metal casing 120d, the tool 200 may be in contact with the first inclined surface S1 and the third inclined surface S3 and move toward the plate 121, so that the first connecting member 122d and the second connecting member 127d are relatively close. The first connecting member 122d and the second connecting member 127d are partially located inside the tool 200. Then, the circuit board 110a may be moved close to the plate 121, so that the opening 112a of the circuit board 110a is aligned with the tool 200, and the circuit board 110a is moved to the position of FIG. 12. Finally, the tool 200 is removed, and the first connecting member 122d and the second connecting member 127d return to their positions in FIG. 10 to engage with the circuit board 110a.

In the process of disassembling circuit board 110a from the metal casing 120d, the tool 200 is first inserted into the opening 112a. At this time, the first inclined surface S1 and the third inclined surface S3 are pushed by the tool 200, so that the first connecting member 122d and the second connecting member 127d are close to each other and located inside the tool 200. The first connecting member 122d and the second connecting member 127d disengage from the circuit board 110a. Then, the circuit board 110a may move along the second axis L2 away from the metal casing 120d and be disassembled.

In addition, the first convex part 123d of the first connecting member 122d and the second convex part 128d of the second connecting member 127d may also be manually pushed to be close to each other, so that the metal casing 120d and the circuit board 110a may be disassembled and assembled without tools. The electronic component 100d of this embodiment has the same effect as the embodiment mentioned above and will not be described again.

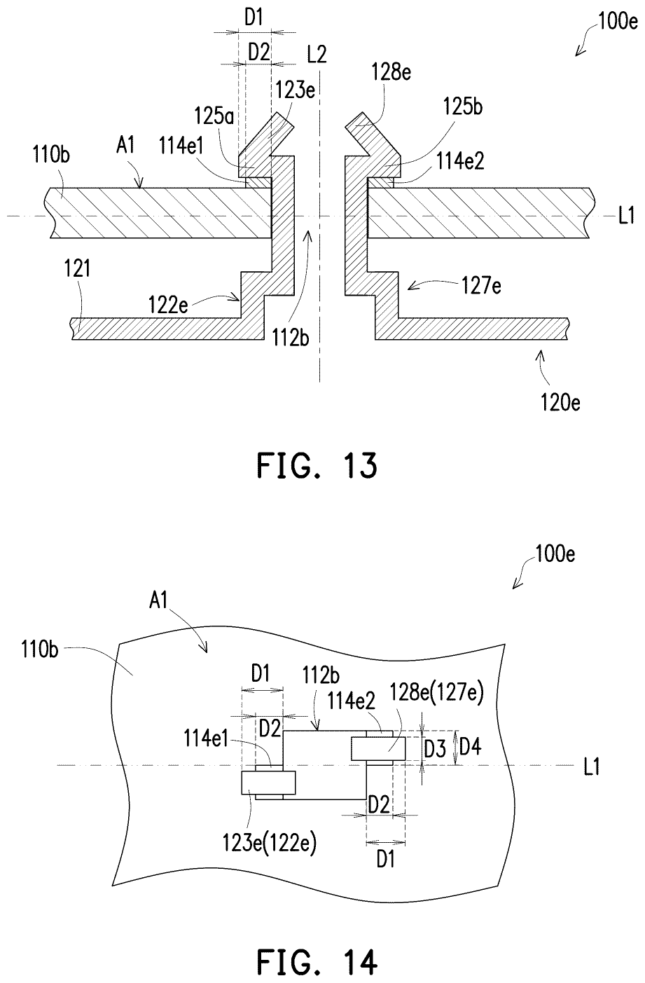

FIG. 13 is a schematic cross-sectional view of an electronic component of another embodiment of this disclosure. FIG. 14 is a top view of an electronic component according to another embodiment of this disclosure. Please refer to FIG. 11, FIG. 13, and FIG. 14 simultaneously. The electronic component 100e of this embodiment is similar to the embodiment mentioned above. The difference between the two is that the number of opening 112b of the circuit board 110b of this embodiment is one, and the shape of the opening 112b is a rectangle. In this embodiment, the number of the pads 114el and 114e2 is two. The two pads 114e1 and 114e2 are arranged on the top surface A1 of the circuit board 110b and are located next to the opening 112b. The pad 114el corresponds to the first connecting member 122e, and the pad 114e2 corresponds to the second connecting member 127e.

From the perspective of FIG. 14, the first convex part 123e of the first connecting member 122e may be regarded as the projection of the horizontal part 125a on the circuit board 110b, and the second convex part 128e of the second connecting member 127e may be regarded as the projection of the horizontal part 125b on the circuit board 110b. The projection of the horizontal parts 125a and 125b onto the top surface A1 of the circuit board 110b has a length D1 along the first axis L1. A length D2 of the pads 114e1 and 114e2 along the first axis L1 is smaller than the length D1 of the corresponding horizontal parts 125a and 125b. The length D1 is, for example, 1 mm, but is not limited thereto.

The surface area of the opening 112b of the circuit board 110b is smaller than the surface area of the opening 112a of the circuit board 110a (see FIG. 11). Thus it is possible to reduce the space requirement in the situation of the assembly of the metal casing 120e and the circuit board 110b, so that the circuit board 110b may have a larger space for wiring and component installation. The electronic component 100e of this embodiment has the same effect as the embodiment mentioned above and will not be described again.

In addition, as shown in FIG. 14, the width D4 of the pads 114e1 and 114e2 perpendicular along the first axis L1 is greater than the width D3 of the corresponding horizontal parts 125a and 125b, but is not limited thereto. In an embodiment not shown, the width of the pads 114e1 and 114e2 may be smaller than or equal to the width of the corresponding horizontal parts 125a and 125b.

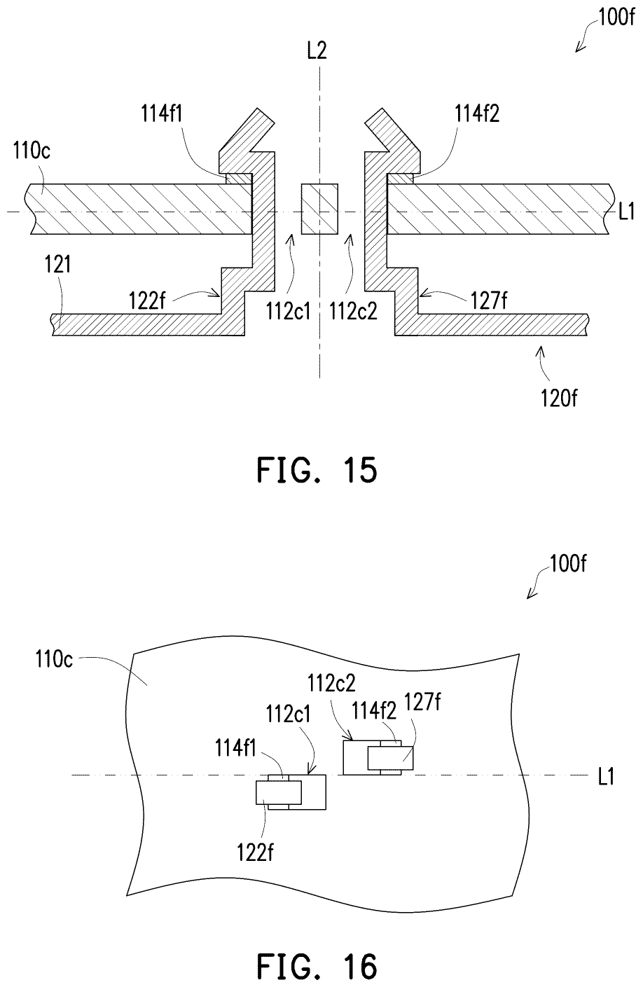

FIG. 15 is a schematic cross-sectional view of an electronic component of another embodiment of this disclosure. FIG. 16 is a top view of the electronic component of FIG. 15. Please refer to FIG. 13, FIG. 15 and FIG. 16 simultaneously. The electronic component 100f of this embodiment is similar to the embodiment mentioned above. The difference between the two is that the circuit board 110c of this embodiment includes two openings 112cl and 112c2 and two pads 114f1 and 114f2. The two pads 114f1 and 114f2 are respectively arranged next to the corresponding two openings 112cl and 112c2. The first connecting member 122f of the metal casing 120f is set up to pass through the opening 112cl and contact the pad 114f1, and the second connecting member 127f is set up to pass through the opening 112c2 and contact the pad 114f2. The two openings 112c1 and 112c2 of the circuit board 110c have a smaller surface area, so that the circuit board 110c may have a larger space for wiring and component installation. The electronic component 100f of this embodiment has the same effect as the embodiment mentioned above and will not be described again.

The set ups and connection relationships of the first connecting member, the second connecting member, the opening, and the pad are not limited to the embodiments mentioned above. The user may set up the first connecting member, the second connecting member, the opening, and the pad according to their requirements.

To sum up, the metal casing of the electronic component of this disclosure is detachably connected to the circuit board through the first connecting member and the second connecting member. The first connecting member and the second connecting member are in contact with the pad of the circuit board so that the circuit board is electrically connected to the plate. The circuit board is easy to assemble onto the metal casing or disassemble from the metal casing.

What is claimed is:

1. An electronic component comprising:
a circuit board, comprising at least one opening and at least one pad; and
a metal casing, wherein the circuit board is detachably connected to the metal casing, the metal casing comprises a plate and a first connecting member and a second connecting member, the plate is connected to the first connecting member and the second connecting member, the first connecting member and the second connecting member partially pass through the at least one opening and are connected to the circuit board, the first connecting member and the second connecting member are in contact with the at least one pad, so that the circuit board is electrically connected to the plate.

2. The electronic component according to claim 1, wherein the plate and the first connecting member and the second connecting member are integrated as a whole.

3. The electronic component according to claim 1, wherein the first connecting member and the second connecting member are staggered on a first axis, and the first axis is parallel to the plate.

4. The electronic component according to claim 1, wherein the first connecting member and the second connecting member are aligned with each other on a first axis, and the first axis is parallel to the plate.

5. The electronic component according to claim 1, wherein the first connecting member comprises a first convex part and a first connecting part connected to each other, at least part of the first connecting part is located in the at least one corresponding opening, the first convex part is exposed on the circuit board from the at least one opening.

6. The electronic component according to claim 5, wherein the first convex part comprises a first inclined surface, the first inclined surface faces away from the circuit board, and the first inclined surface is pushed by a bottom surface of the circuit board, so that the first connecting member is moved closer to the second connecting member, the bottom surface faces the plate.

7. The electronic component according to claim 6, wherein the first convex part comprises a second inclined surface, the second inclined surface faces the circuit board, and the second inclined surface is pushed by a top surface of the circuit board, so that the first connecting member is moved closer to the second connecting member, and the top surface faces away from the plate.

8. The electronic component according to claim 6, wherein the first convex part comprises a horizontal part, the horizontal part is connected to the first inclined surface and is parallel to a first axis, and the first axis is parallel to the plate.

9. The electronic component according to claim 5, wherein the first convex part comprises an arc surface.

10. The electronic component according to claim 5, wherein the first connecting member further comprises a positioning part, the positioning part is connected between the first connecting part and the plate in a bending manner, the positioning part is adapted to block the circuit board from moving along a second axis, the second axis is perpendicular to the circuit board.

11. The electronic component according to claim 1, wherein each of the at least one pad is connected to an inner wall surface of each of the at least one corresponding opening.

12. The electronic component according to claim 1, wherein each of the at least one pad surrounds each of the at least one opening and is located on a top surface of the circuit board, and the top surface faces away from the plate.

13. The electronic component according to claim 1, wherein each of the at least one pad comprises a first part and a second part connected to each other, the first part is located on a top surface of the circuit board, and the second part is connected to an inner wall surface of each of the at least one corresponding opening, the top surface faces away from the plate.

14. The electronic component according to claim 13, wherein the first connecting member comprises a first convex part and a first connecting part connected to each other, the first convex part contacts the first part, and the first connecting part contacts the second part.

15. The electronic component according to claim 1, wherein the number of the at least one opening is two, the number of the at least one pad is two, and the first connecting member is set up to pass through one of the two openings and contacts one of the two pads, wherein the second connecting member is set up to pass through the other of the two openings and contacts the other of the two pads.

16. The electronic component according to claim 1, wherein a projection part of at least one of the first connecting member and the second connecting member to the circuit board is located in the opening.

17. The electronic component according to claim 1, wherein the second connecting member comprises a second convex part and a second connecting part connected to each other, at least part of the second connecting part is located in the at least one corresponding opening, the second convex part is exposed on the circuit board from the at least one opening.

18. The electronic component according to claim 17, wherein the second connecting member further comprises a positioning part, the positioning part is connected between the second connecting part and the plate in a bending manner, the positioning part is adapted to block the circuit board from moving along a second axis, the second axis is perpendicular to the circuit board.

19. The electronic component according to claim 17, wherein the second convex part of the second connecting member comprises a third inclined surface, and the third inclined surface faces away from the circuit board.

20. The electronic component according to claim 1, wherein the circuit board is coupled to the plate through the first connecting member and the second connecting member and is grounded.
